(19) United States
(12) Patent Application Publication
(10) Pub. No.: US 2019/0006294 A1
(43) Pub. Date: Jan. 3, 2019

(54) STIFFENER FOR A PACKAGE SUBSTRATE

(71) Applicant: Intel Corporation, Santa Clara, CA (US)

(72) Inventors: Jenny Shio Yin Ong, Bayan Lepas (MY); Seok Ling Lim, Kulim (MY); Kang Eu Ong, Spg Ampat (MY); Bok Eng Chea, Gelugor (MY); Jackson Chung Peng Kong, Tanjung Tokong (MY)

(73) Assignee: Intel Corporation, Santa Clara, CA (US)

(21) Appl. No.: 16/002,926

(22) Filed: Jun. 7, 2018

(30) Foreign Application Priority Data
Jun. 30, 2017 (MY) PI 2017702407

(51) Int. Cl. H01L 23/00; H01L 23/552

(52) U.S. Cl. CPC H01L 23/562; H01L 23/552; H01L 2924/3511; H01L 2924/15311; H01L 24/17

(57) ABSTRACT

Stiffener technology for electronic device packages is disclosed. A stiffener for a package substrate can include a top portion configured to be affixed to a top surface of a package substrate. The stiffener for a package substrate can also include a lateral portion extending from the top portion and configured to be disposed about a lateral side of the package substrate. An electronic device package and associated systems and methods are also disclosed.

### PRIORITY DATA

This application claims priority to Malaysian Patent Application No. PI 2017702407, filed Jun. 30, 2017, which is incorporated herein by reference in its entirety.

### TECHNICAL FIELD

Embodiments described herein relate generally to electronic device packages, and more particularly to stiffeners for package substrates.

### BACKGROUND

Many computing devices, including mobile, tablet, and ultrabook technologies, require components with increasingly reduced dimensions. Consequently, package substrates are becoming thinner, which renders them susceptible to mechanical warpage when components are surface mounted (SMT) on the package substrates. This often results in surface mounting yield loss due to solder ball non-connect opens during surface mounting reflow processes. To mitigate package warpage during surface mounting, package core thickness may be increased or a package stiffener may be attached to a top surface of a package substrate to provide greater mechanical strength.

### BRIEF DESCRIPTION OF THE DRAWINGS

Invention features and advantages will be apparent from the detailed description which follows, taken in conjunction with the accompanying drawings, which together illustrate, by way of example, various invention embodiments; and, wherein:

FIG. 1A illustrates a perspective view of an electronic device package in accordance with an example embodiment;

FIG. 1B illustrates a side view of the electronic device package of FIG. 1A in accordance with an example embodiment;

FIG. 1C illustrates a top view of the electronic device package of FIG. 1A in accordance with an example embodiment;

FIG. 1D illustrates a bottom view of the electronic device package of FIG. 1A in accordance with an example embodiment;

FIG. 2 illustrates a bottom view of an electronic device package in accordance with an example embodiment;

FIG. 3 illustrates a bottom view of an electronic device package in accordance with an example embodiment;

FIGS. 4A-4G illustrate side views of a method for coupling a stiffener to a package substrate in accordance with an example embodiment;

FIGS. 5A-5G illustrate top views of a method for coupling a stiffener to a package substrate in accordance with an example embodiment; and

FIG. 6 is a schematic illustration of an exemplary computing system.

Reference will now be made to the exemplary embodiments illustrated, and specific language will be used herein to describe the same. It will nevertheless be understood that no limitation of the scope or to specific invention embodiments is thereby intended.

### DESCRIPTION OF EMBODIMENTS

Before invention embodiments are disclosed and described, it is to be understood that no limitation to the particular structures, process steps, or materials disclosed herein is intended, but also includes equivalents thereof as would be recognized by those ordinarily skilled in the relevant arts. It should also be understood that terminology employed herein is used for the purpose of describing particular examples only and is not intended to be limiting. The same reference numerals in different drawings represent the same element. Numbers provided in flow charts and processes are provided for clarity in illustrating steps and operations and do not necessarily indicate a particular order or sequence. Unless defined otherwise, all technical and scientific terms used herein have the same meaning as commonly understood by one of ordinary skill in the art to which this disclosure belongs.

As used in this written description, the singular forms “a,” “an” and “the” provide express support for plural referents unless the context clearly dictates otherwise. Thus, for example, reference to “a layer” includes a plurality of such layers.

In this application, “comprises,” “comprising,” “containing” and “having” and the like can have the meaning ascribed to them in U.S. Patent law and can mean “includes,” “including,” and the like, and are generally interpreted to be open ended terms. The terms “consisting of” or “consists of” are closed terms, and include only the components, structures, steps, or the like specifically listed in conjunction with such terms, as well as that which is in accordance with U.S. Patent law. “Consisting essentially of” or “consists essentially of” have the meaning generally ascribed to them by U.S. Patent law. In particular, such terms are generally closed terms, with the exception of allowing inclusion of additional items, materials, components, steps, or elements, that do not materially affect the basic and novel characteristics or function of the item(s) used in connection therewith. For example, trace elements present in a composition, but not affecting the composition's nature or characteristics would be permissible if present under the “consisting essentially of” language, even though not expressly recited in a list of items following such terminology. When using an open-ended term in the written description like “comprising” or “including,” it is understood that direct support should be afforded also to “consisting essentially of” language as well as “consisting of” language as if stated explicitly and vice versa.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments described herein are, for example, capable of operation in other orientations than those illustrated or otherwise described herein.

The term “coupled,” as used herein, is defined as directly or indirectly connected in an electrical or nonelectrical manner. “Directly coupled” objects or elements are in physical contact with one another. Objects described herein as being “adjacent to” each other may be in physical contact with each other, in close proximity to each other, or in the same general region or area as each other, as appropriate for the context in which the phrase is used. Occurrences of the phrase “in one embodiment,” or “in one aspect,” herein do not necessarily all refer to the same embodiment or aspect.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, sizes, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

Reference throughout this specification to “an example” means that a particular feature, structure, or characteristic described in connection with the example is included in at least one embodiment. Thus, appearances of the phrases “in an example” in various places throughout this specification are not necessarily all referring to the same embodiment.

Furthermore, the described features, structures, or characteristics may be combined in any suitable manner in one or more embodiments. In this description, numerous specific details are provided, such as examples of layouts, distances, network examples, etc. One skilled in the relevant art will recognize, however, that many variations are possible without one or more of the specific details, or with other methods, components, layouts, measurements, etc. In other instances, well-known structures, materials, or operations are not shown or described in detail but are considered well within the scope of the disclosure.

### Example Embodiments

An initial overview of technology embodiments is provided below and specific technology embodiments are then described in further detail. This initial summary is intended to aid readers in understanding the technology more quickly but is not intended to identify key or essential features of the technology nor is it intended to limit the scope of the claimed subject matter.

Although increasing package core thickness may provide sufficient mechanical strength to mitigate package warpage concerns, the potential tradeoffs are increased package substrate thickness, footprint size, and power integrity degradation. Implementation of a package stiffener attached to a top surface of a package substrate may be adequate for some relatively small X-Y form factor applications, but may not be sufficient to eliminate package warpage concerns in larger X-Y form factor applications.

Accordingly, stiffeners for a package substrate that eliminate package warpage concerns for thin package substrates in small and large X-Y form factor applications are disclosed. In one aspect, the stiffener can provide warpage control during both room temperature and high-temperature (˜230° C.) conditions to improve surface mounting assembly yield. In one example embodiment, a stiffener for a package substrate can include a top portion configured to be affixed to a top surface of a package substrate. The stiffener for a package substrate can also include a lateral portion extending from the top portion and configured to be disposed about a lateral side of the package substrate. Electronic device packages and associated systems and methods are also disclosed.

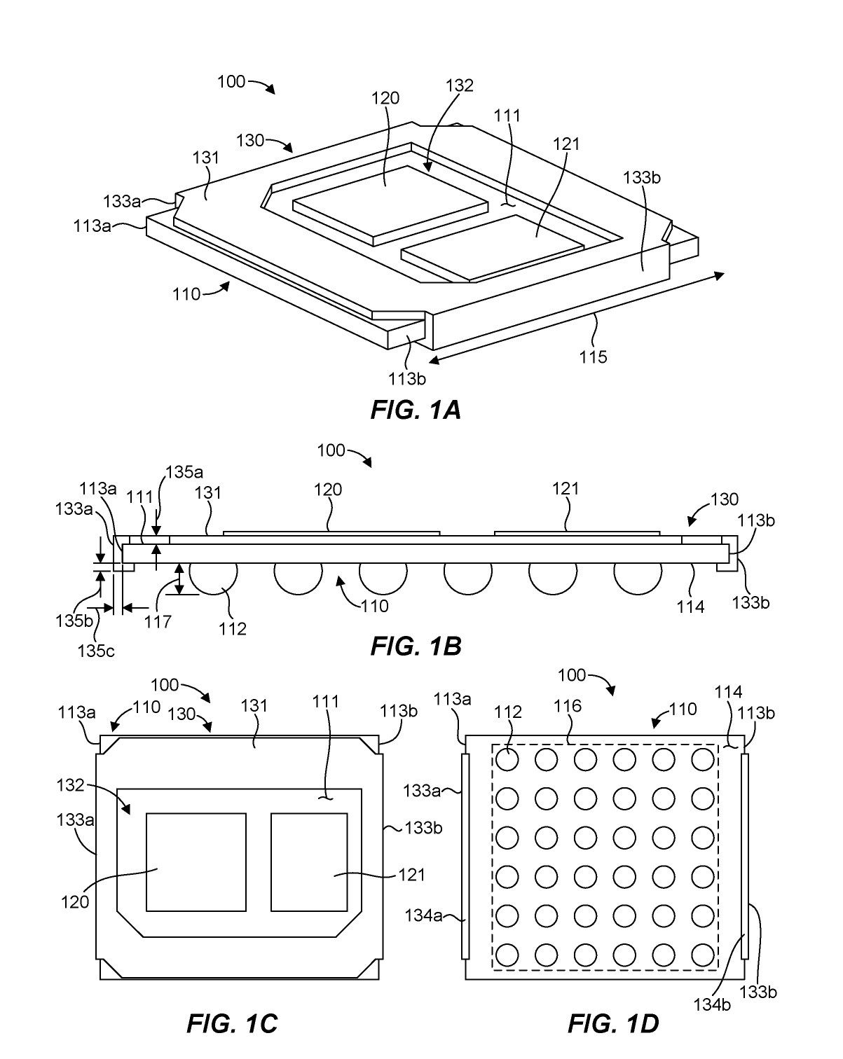

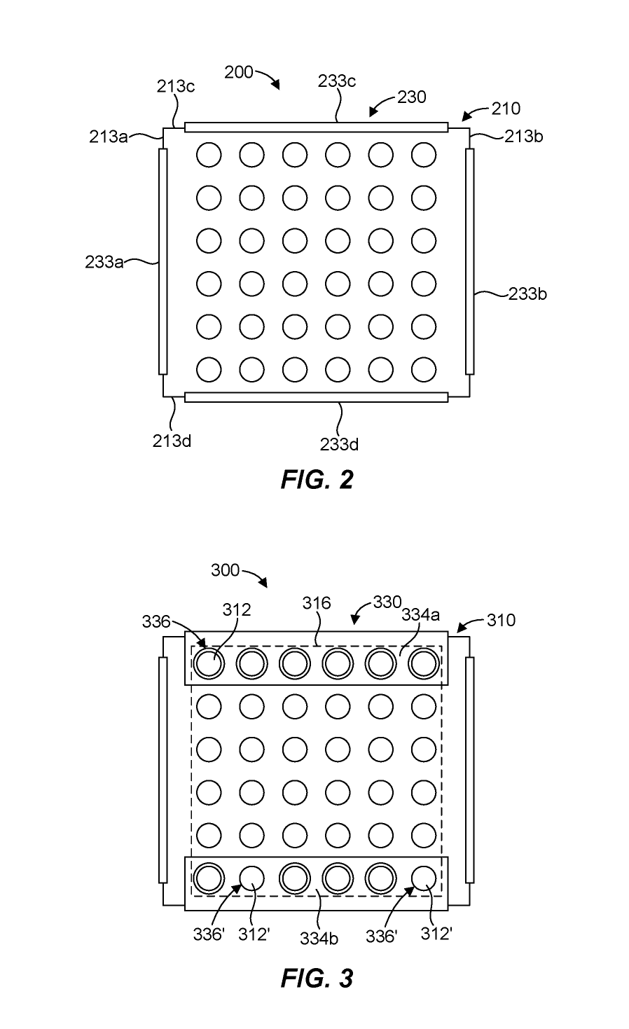

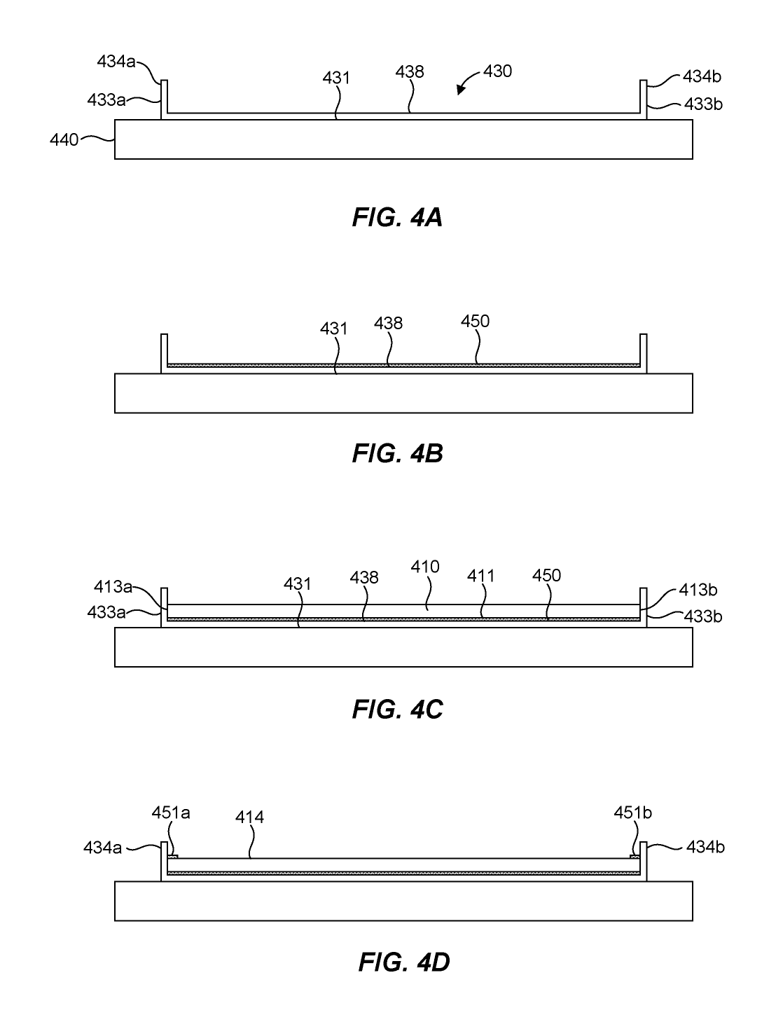

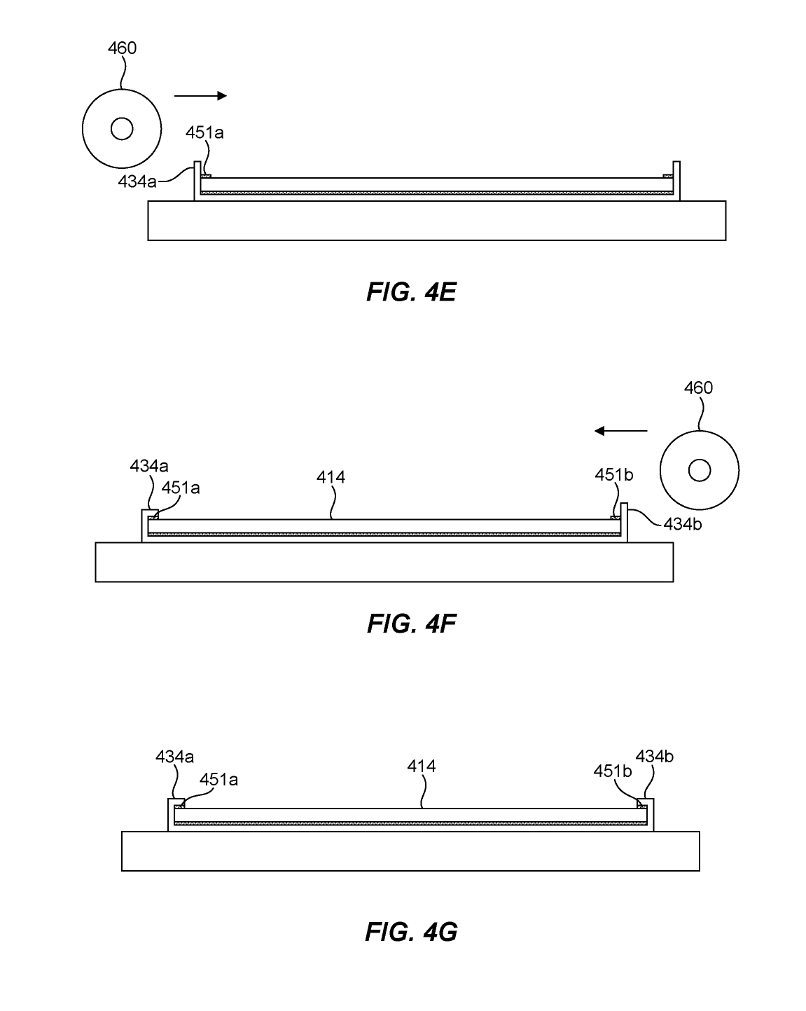

Referring to FIGS. 1A-1D, an exemplary electronic device package 100 is illustrated in various views. The package 100 is shown in perspective, side, top, and bottom views in FIGS. 1A-1D, respectively. In general, the electronic device package 100 can include a package substrate 110, one or more electronic components 120, 121 operably coupled to a top surface 111 of the substrate 110, and a stiffener 130. The combination of the stiffener 130 and the package substrate 110 can form a reinforced package substrate. The stiffener 130 can function to mechanically strengthen the package 100 (e.g., minimize warpage of the substrate 110 at room temperature and/or at high temperature (˜230° C.) conditions.

An electronic component can be any electronic device or component that may be included in an electronic device package, such as a semiconductor device (e.g., a die, a chip, a processor, computer memory, a platform controller hub, etc.). In one embodiment, each of the electronic components 120, 121 may represent a discrete chip. The electronic components 120, 121 may be, include, or be a part of a processor (e.g., a CPU, a GPU, etc.), a memory device (e.g., SRAM, DRAM, flash memory, EEPROM, etc.), an application specific integrated circuit (ASIC), a platform controller hub (PCH), a field programmable gate array (FPGA), a system on a chip (SOC), a system in a package (SIP), or a package on a package (POP) in some embodiments. Although two electronic components 120, 121 are depicted in FIGS. 1A-1C, any suitable number of electronic components can be included.

The substrate 110 may include typical substrate materials. For example, the substrate 110 may comprise an epoxy-based laminate substrate having a core and/or build-up layers. The substrate 110 may include other suitable types of substrates in other embodiments. For example, the substrate can be formed primarily of any suitable semiconductor material (e.g., a silicon, gallium, indium, germanium, or variations or combinations thereof, among other substrates), one or more insulating layers, such as glass-reinforced epoxy, such as FR-4, polytetrafluoroethylene, cotton-paper reinforced epoxy (CEM-3), phenolic-glass (G3), paper-phenolic (FR-1 or FR-2), polyester-glass (CEM-5), ABF (Ajinomoto Build-up Film), any other dielectric material, such as glass, or any combination thereof, such as can be used in printed circuit boards (PCBs).

The electronic components 120, 121 can be attached to the substrate 110 according to a variety of suitable configurations including a flip-chip configuration, wire bonding, and the like. The electronic components 120, 121 can be electrically coupled to the substrate 110 using interconnect structures (e.g., solder balls and/or wire bonds, not shown) configured to route electrical signals between the electronic components 120, 121 and the substrate 110. In some embodiments, the interconnect structures may be configured to route electrical signals such as, for example, I/O signals and/or power or ground signals associated with the operation of the electronic components 120, 121.

The substrate 110 may include electrically conductive elements or electrical routing features (not shown) configured to route electrical signals to or from the electronic components 120, 121. The electrical routing features may be internal (e.g., disposed at least partially within a thickness of the substrate 110) and/or external to the substrate 110. For example, in some embodiments, the substrate 110 may include electrical routing features such as pads, vias, and/or traces configured to receive the interconnect structures and route electrical signals to or from the electronic components 120, 121. The pads, vias, and traces can be constructed of the same or similar electrically conductive materials, or of different electrically conductive materials. The electronic device package 100 can also include interconnects 112, such as solder balls, for coupling with a substrate (e.g., a circuit board such as a motherboard) for power and/or signaling.

The stiffener 130 can have a top portion 131 configured to be affixed to the top surface 111 of the package substrate 110. The top portion 131 of the stiffener 120 can have an opening 132 configured with a shape and/or size to accommodate the electronic components 120, 121. In some embodiments, the electronic components 120, 121 can extend at least partially through the opening 132. The top portion 131 of the stiffener 130 can be disposed about a periphery of the package substrate 110 (e.g., adjacent to the peripherals of the electronic components 120, 121) to provide mechanical support for warpage control. For example, as shown in FIGS. 1A and 1C, the shape or geometry of the top portion 131 of the stiffener 130 can comprise a ring or “picture frame” configuration. In such a configuration, a top profile of the shape can include the interior opening 132, and the electronic components 120, 121 can be disposed in the opening 132. In other words, the top portion 131 of the stiffener 130 can form a structure about the periphery of the electronic components 120, 121 that surrounds or substantially surrounds and “frames” the electronic components on the package substrate 110.

The stiffener 130 can also have one or more lateral portions 133a, 133b extending from the top portion 132. The lateral portions 133a, 133b can be configured to be disposed about lateral sides 113a, 113b, respectively, of the package substrate 110. The lateral portions 133a, 133b of the stiffener 130 can be in contact with the respective lateral sides 113a, 113b of the package substrate 110, which can enhance the coupling of the stiffener 130 and the package substrate 110 and therefore enhance the mechanical stiffness or rigidity of the stiffener/substrate combination. In some embodiments, the lateral portions 133a, 133b can be coupled to, including directly coupled or fixed to, lateral sides 113a, 113b. In other embodiments the lateral portions 133a, 133b are merely in contact with, or not in contact with lateral sides 113a, 113b. In one embodiment, two lateral portions 133a, 133b can be disposed about opposite lateral sides 113a, 113b of the package substrate 110 to provide balanced reaction of forces and moments from the package substrate 110. In other words, such a symmetrical configuration of the stiffener 130 can serve to provide opposing forces and moments acting on the package substrate 110 that tend to resist warpage of the substrate 110.

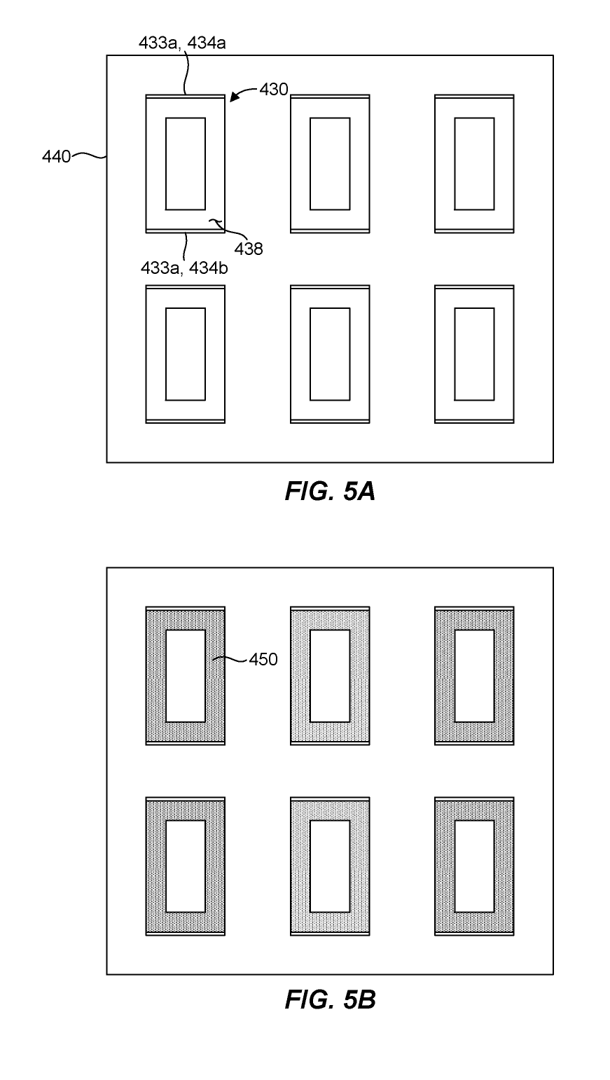

FIG. 2 shows an example of an electronic device package 200 where four lateral portions 233a-d of a stiffener 230 are disposed about all four respective lateral sides 213a-d of a package substrate 210. Specifically, two lateral portions 233a, 233b are disposed about opposite lateral sides 213a, 213b of the package substrate 210, and two lateral portions 233c, 233d are disposed about opposite lateral sides 213c, 213d of the package substrate 210. In this case, the lateral portions 233a-d of the stiffener 230 can react to forces and moments from all sides of the package substrate 210 for improved warpage control.

Although the package substrates illustrated herein are rectangular in shape (i.e., four lateral sides), a package substrate can be of any suitable shape and have any number of lateral sides. Accordingly, it should be recognized that a stiffener as disclosed herein can be configured to fit any shape of package substrate.

With further reference to FIGS. 1A-1D, in one aspect, the lateral portions 133a, 133b of the stiffener 130 can extend at least partially about the respective lateral sides 113a, 113b between the top surface 111 and a bottom surface 114 of the package substrate 110. For example, in the illustrated embodiment, the lateral portions 133a, 133b of the stiffener 130 extend the entire thickness of the respective lateral sides 113a, 113b from the top surface 111 to the bottom surface 114 of the package substrate 110. In another embodiment (not shown), the lateral portions 133a, 133b of the stiffener 130 may extend only partially along the thickness of the respective lateral sides 113a, 113b from the top surface 111 to the bottom surface 114 of the package substrate 110.

In one aspect, the lateral portions 133a, 133b of the stiffener 130 may not equal a width dimension 115 of the lateral sides 113a, 113b of the package substrate 110. For example, as shown in FIG. 1A, the lateral portions 133a, 133b of the stiffener 130 extend less than the entire width dimension 115 of the lateral sides 113a, 113b of the package substrate 110. Although the lateral portions 133a, 133b are each shown as being a single continuous and uninterrupted structure in the width dimension 115, it should be recognized that the lateral portions 133a, 133b may be segmented in the width dimension 115 (e.g., in two or more segments or “fingers”). Thus, the lateral portions 133a, 133b of the stiffener 130 can be disposed about less than 100% of an area of the respective lateral sides 113a, 113b of the package substrate 110. However, to provide adequate structural reinforcement, the lateral portions 133a, 133b of the stiffener 130 can be disposed about greater than or equal to 20% of an area of the respective lateral sides 113a, 113b of the package substrate 110.

In one aspect, the stiffener 130 can optionally include one or more bottom portions 134a, 134b extending from the respective lateral portions 133a, 133b. The bottom portions 134a, 134b can be disposed proximate the bottom surface 114 of the package substrate 110. The bottom portions 134a, 134b of the stiffener 130 can extend from 100 μm to 1 mm (to 700 μm in some embodiments) from the respective lateral sides 113a, 113b of the package substrate 110 along the bottom surface 114. The top portion 131, the lateral portions 133a-b, and the bottom portions 134a-b can have any suitable thickness. For example, the top, lateral, and bottom portions of the stiffener 130 can each have respective thicknesses 135a-c of from 50 μm to 200 μm. The thicknesses 135a-c of the top, lateral, and bottom portions of the stiffener 130 may be the same or different. In one aspect, the thickness 135b of the bottom portions 134a, 134b may be sized to avoid interference with an underlying component to which the package 100 may be attached, such as a substrate (e.g., a circuit board such as a motherboard). For example, the thickness 135b of the bottom portions 134a, 134b may be less than a height 117 of the solder balls 112 to avoid interference with an underlying component.

The stiffener 130 can be made of any structural material with suitable mechanical properties, such as a relatively high strength and/or high hardness material. Other suitable structural material properties include ductility and malleability. Some examples of structural materials include metals, ceramics, polymers, composites (e.g., fiber reinforced resin and metal matrix composites), glass, etc. A suitable metal material may include steel (e.g., iron alloys such as stainless steel, carbon steel, etc.), aluminum (e.g., aluminum alloys), magnesium (e.g., magnesium alloys), copper (e.g., copper alloys), nickel (e.g., nickel alloys), etc. A single structural material can be included or multiple structural materials in any combination. In one aspect, the top portion 131, the lateral portions 133a-b, and the bottom portions 134a-b of the stiffener 130 in any combination can form a single monolithic structure. Thus, in some embodiments, the entire stiffener 130 can be a single monolithic structure.

In addition to having advantageous physical properties, the stiffener 130 can have a shape configured to provide mechanical support for the substrate 110. As shown in FIG. 1B, a side profile of the stiffener 130 can comprise a C shape (i.e., formed by the top portion 131, the lateral portions 133a-b, and the bottom portions 134a-b of the stiffener 130). This C-shape can provide an area moment of inertia that resists bending (e.g., due to substrate warpage) along the length of the lateral sides 113a, 113b of the package substrate 110 (i.e., in the width dimension 115 of the lateral sides 113a, 113b of the package substrate 110). In one aspect, a shape or geometry of the stiffener 130 can be provided with a suitable area moment of inertia about an axis of interest to provide suitable bending stiffness for a given application.

In one aspect, the top portion 131, the lateral portions 133a-b, and/or the bottom portions 134a-b of the stiffener 130 can be affixed to the package substrate 110. For example, the top portion 131 of the stiffener 130 can be affixed to the top surface 111 of the substrate 110, the lateral portions 133a-b of the stiffener 130 can be affixed to the lateral surfaces 113a-b of the substrate 110, and/or the bottom portions 134a-b of the stiffener 130 can be affixed to the bottom surface 114 of the substrate 110. The stiffener 130 can be affixed (i.e., mechanically coupled or otherwise attached) to the package substrate 110 in any suitable manner. For example, an adhesive (not shown) can be used to affix the stiffener 130 to the substrate 110. The stiffener 130 can be affixed to the substrate 110 at selected or spot interface locations or continuously about an interface, which can affect the bending stiffness of the package 100. Any suitable adhesive (e.g., epoxy cement, alumina or silicate-based ceramic adhesive, urethane adhesive, polyimide adhesive, etc.) may be utilized, such as an electrically conductive and/or an electrically non-conductive adhesive. For example, an electrically conductive and/or non-conductive adhesive may be used when the stiffener 130 is made of an electrically conductive material. In one aspect, an electrically conductive adhesive can be disposed such that the adhesive will be in contact with ground pads (not shown) on the package substrate 110 and the stiffener 130 to ground the stiffener and thereby enable the stiffener 130 to provide electromagnetic interference (EMI) or radio-frequency interference (RFI) shielding benefits when the stiffener is made of an electrically conductive material.

As illustrated in FIG. 1D, the package substrate 110 can have a ball grid array (BGA) region 116. The BGA region 116 is an area or zone (e.g., a “footprint”) on the bottom surface 114 of the substrate 110 where the solder balls 112 are disposed. In the embodiment shown in FIG. 1D, the bottom portions 134a, 134b of the stiffener 130 are maintained outside the BGA region 116 about a periphery of the bottom surface 114 of the package substrate 110. It should be recognized that the BGA region 116 can have any suitable shape or configuration.

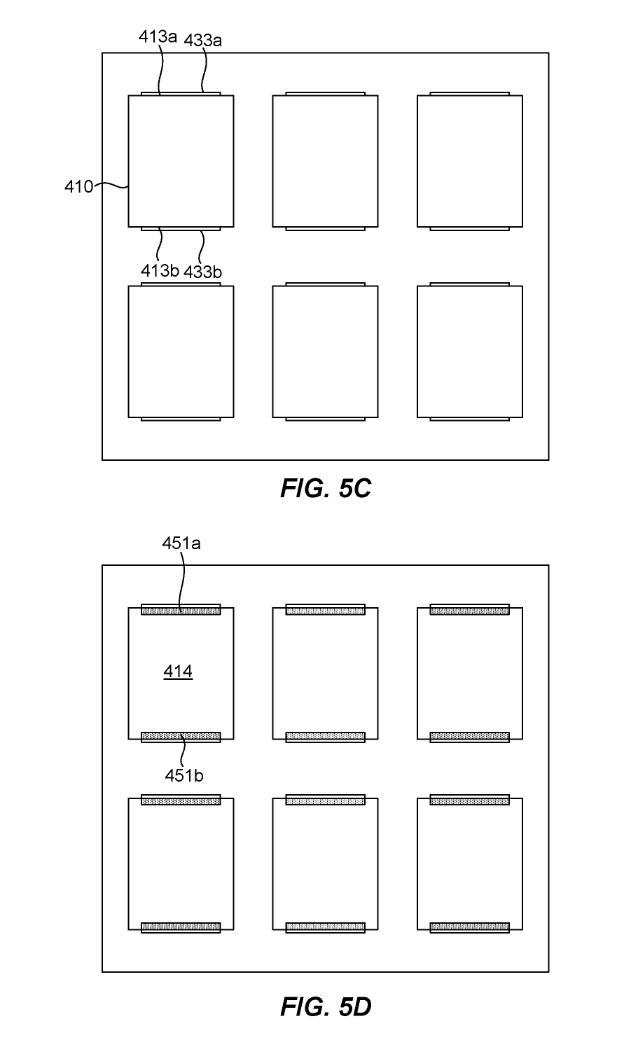

FIG. 3 illustrates an embodiment of an electronic device package 300 where bottom portions 334a, 334b of a stiffener 330 extend into a BGA region 316 of a package substrate 310 for enhanced mechanical performance. In this case, the bottom portions 334a, 334b of the stiffener 330 include openings 336. The openings 336 are configured such that solder balls 312 can be disposed in the openings 336. The openings 336 can be configured to provide a space or gap between the bottom portions 334a-b of the stiffener 330 and the solder balls 312 such that there is clearance sufficient to avoid electrical short circuits or arcing. In some embodiments, an electrically non-conductive material (e.g., an epoxy polymer) can be disposed between the bottom portions 334a, 334b of the stiffener 330 and the solder balls 312 to avoid electrical short circuits or arcing.

In some embodiments, the stiffener 330 (e.g., when made of an electrically conductive material) can be configured to electrically couple to one or more solder balls (e.g., solder balls 312′) through at least one of the bottom portions 334a, 334b to provide electromagnetic shielding for signal transmission lines and/or electronic components that reside on and/or within the electronic device package 300. For example, the solder balls 312′ can be electrically associated with a reference voltage source (e.g., a Vss ground reference voltage or a power reference voltage) through conductive routing and structures (not shown) within the package substrate 310. In one embodiment, the bottom portions 334a, 334b may be directly coupled to the solder balls 312′ through sidewalls of the openings 336′. In this case, the openings 336′ can be sized such that there is no space or gap between the solder balls 312′ and at least one of the bottom portions 334a, 334b of the stiffener 330. In one aspect, the openings 336 that accommodate solder balls 312 can be larger in diameter compared to the openings 336′ that accommodate solder balls 312′. Alternatively, the openings 336, 336′ that accommodate the respective solder balls 312, 312′ can be the same size (i.e., same diameter) but the solder balls 312′ may be larger in diameter than the solder balls 312.

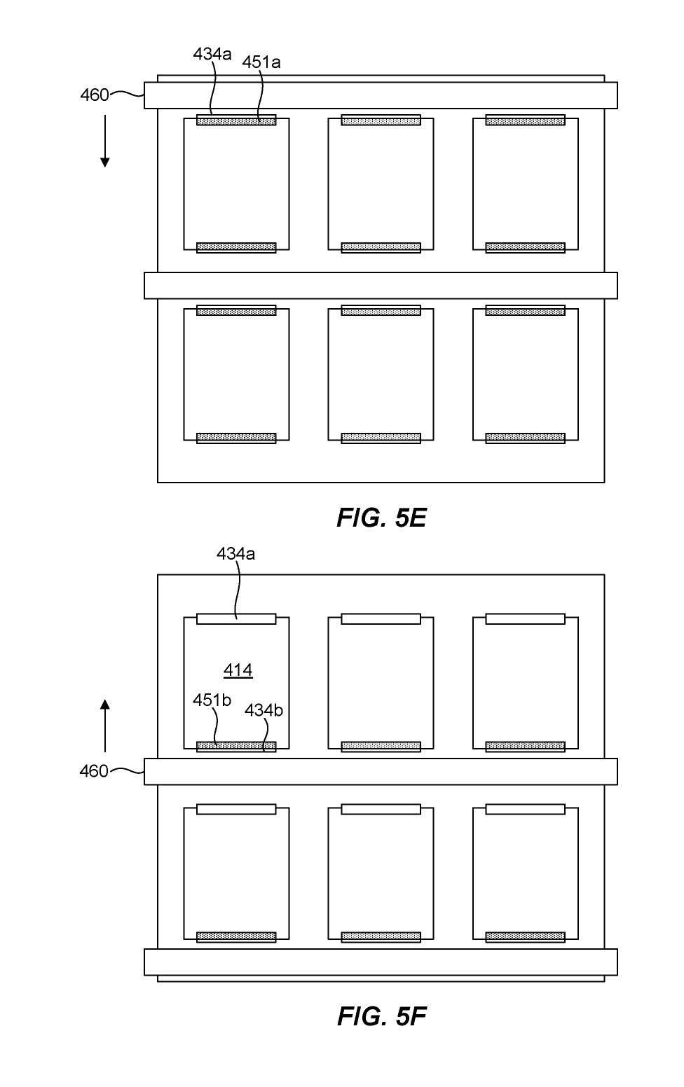

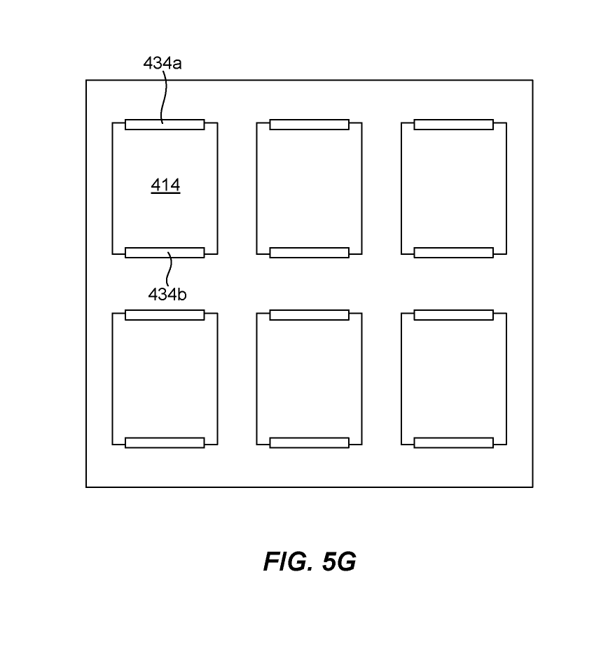

FIGS. 4A-4G and FIGS. 5A-5G illustrate various aspects of a method for coupling a stiffener to a package substrate. FIGS. 4A-4G show side views and FIGS. 5A-5G show top views illustrating the method. FIGS. 5A-5G also illustrate how multiple stiffeners can be coupled to multiple package substrates simultaneously, although reference will be made to only one stiffener/substrate combination for simplicity. In general, a stiffener 430 having a top portion 431 and lateral portions 433a, 433b extending from the top portion 431 can be affixed to a package substrate 410, such that an underside 438 of the top portion 431 of the stiffener 430 is proximate to a top surface 411 of the package substrate 410, and the lateral portions 433a, 433b of the stiffener 430 are disposed about lateral sides 413a, 413b of the package substrate 410.

Specifically, as shown in FIGS. 4A and 5A, the top portion 431 of the stiffener 430 can be disposed on a carrier 440 with the underside 438 of the top portion 431 exposed and the lateral portions 433a, 433b of the stiffener 430 extending away from the carrier 440. At this point in the process, the stiffener 430 can have a U-shape or configuration. In some embodiments, bottom portions 434a, 434b can extend from the respective lateral portions 433a, 433b of the stiffener 430.

The top surface 411 of the package substrate 410 can be affixed to the underside 438 of the top portion 431 of the stiffener 430 by disposing an adhesive 450 on the underside 438 of the top portion 431 of the stiffener 430, as shown in FIGS. 4B and 5B, and disposing the top surface 411 of the package substrate 410 on the underside 438 of the top portion 431 of the stiffener 430 (i.e., on the adhesive 450), as shown in FIGS. 4C and 5C. The lateral portions 433a, 433b of the stiffener 430 can be in contact with the respective lateral sides 413a, 413b of the package substrate 410. It should be recognized that adhesive can be disposed on the top surface 411 of the package substrate 410 in addition or as an alternative to disposing adhesive on the underside 438 of the top portion 431 of the stiffener 430. Adhesive can be disposed on the underside 438 of the top portion 431 of the stiffener 430 in any suitable manner, such as dispensed (e.g., sprayed), applied in a pre-formed strip or sheet, etc. The mechanical bonding between the adhesive 450 and the top surface 411 may be performed through reflow and/or a thermal compression bonding process, for example. In one aspect, an electrically conductive adhesive can be disposed such that the adhesive will be in contact with ground pads (not shown) on the package substrate 410 and the stiffener 430 to ground the stiffener and thereby minimize or avoid electromagnetic interference (EMI) or radio-frequency interference (RFI) issues when the stiffener 430 is made of an electrically conductive material.

The bottom portions 434a, 434b of the stiffener 430 can be affixed to a bottom surface 414 of the package substrate 410 by disposing an adhesive 451a, 451b on the bottom surface 414 of the package substrate 410, as shown in FIGS. 4D and 5D, and disposing the bottom portions 434a, 434b of the stiffener 430 proximate the bottom surface 414 of the package substrate 410 (i.e., on the adhesive 451a, 451b), as shown in FIGS. 4E-4F and 5E-5F to arrive at the configuration shown in FIGS. 4G and 5G. It should be recognized that adhesive can be disposed on the bottom portions 434a, 434b of the stiffener 430 in addition or as an alternative to disposing adhesive on the bottom surface 414 of the package substrate 410. The bottom portions 434a, 434b of the stiffener 430 can be disposed proximate the bottom surface 414 of the package substrate 410 by any suitable technique or process, such as bending the bottom portions 434a, 434b of the stiffener 430. The bottom portions 434a, 434b of the stiffener 430 can be bent by any suitable technique or process, such as rolling the bottom portions 434a, 434b of the stiffener 430. For example, as shown in FIGS. 4E-4F and 5E-5F, a roller 460 can roll the bottom portion 434a into contact with the adhesive 451a on the bottom surface 414 of the package substrate 410 and then roll the bottom portion 434b into contact with the adhesive 451b on the bottom surface 414 of the package substrate 410. In an embodiment, the mechanical bonding between the adhesive 451a, 451b and bottom surface 414 may be performed through reflow and/or a thermal compression bonding through the roller 460, for example.

The method can be used to couple stiffeners as disclosed herein to package substrates (e.g., as in FIGS. 1A-3), including the FIG. 3 embodiment where bottom portions of the stiffener extend into the BGA region of the package substrate. Solder balls and electronic components can be added to the substrate to complete the package.

It should be recognized that a stiffener can be formed in any suitable manner and can be coupled to a package substrate in any suitable manner. For example, a stiffener can be molded (e.g., made of a polymer material) into a suitable shape prior to assembly with the package substrate. Such a stiffener can be cured or hardened once assembled with the substrate. In another example, a stiffener can be formed by deposition directly onto a package substrate and therefore formed in situ.

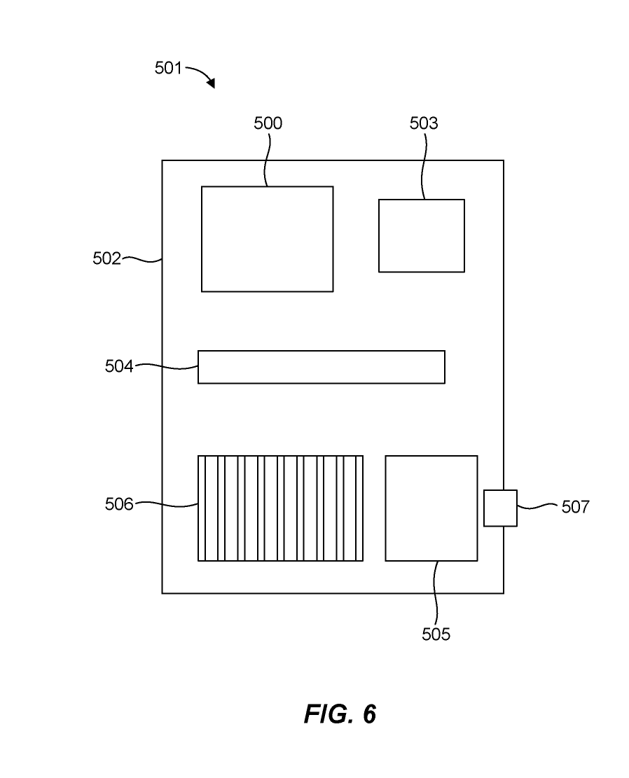

FIG. 6 illustrates an example computing system 501. The computing system 501 can include an electronic device package 500 as disclosed herein, coupled to a motherboard 502. In one aspect, the computing system 501 can also include a processor 503, a memory device 504, a radio 505, a heat sink 506, a port 507, a slot, or any other suitable device or component, which can be operably coupled to the motherboard 502. The computing system 501 can comprise any type of computing system, such as a desktop computer, a laptop computer, a tablet computer, a smartphone, a wearable device, a server, etc. Other embodiments need not include all of the features specified in FIG. 6, and may include alternative features not specified in FIG. 6.

### EXAMPLES

The following examples pertain to further embodiments.

In one example, there is provided a stiffener for a package substrate comprising a top portion configured to be affixed to a top surface of a package substrate, and a lateral portion extending from the top portion and configured to be disposed about a lateral side of the package substrate.

In one example of a stiffener for a package substrate, the lateral portion is configured to be in contact with the lateral side of the package substrate.

In one example of a stiffener for a package substrate, the lateral portion is configured to extend at least partially about the lateral side between the top surface and a bottom surface of the package substrate.

In one example of a stiffener for a package substrate, the lateral portion is configured to extend about the lateral side from the top surface to a bottom surface of the package substrate.

In one example of a stiffener for a package substrate, the lateral portion is configured to be disposed about greater than or equal to 20% of an area of the lateral side of the package substrate.

In one example of a stiffener for a package substrate, the top portion is configured to be affixed to the top surface of the package substrate with an adhesive.

In one example of a stiffener for a package substrate, the adhesive is an electrically non-conductive adhesive.

In one example of a stiffener for a package substrate, the adhesive is an electrically conductive adhesive.

In one example of a stiffener for a package substrate, the top and lateral portions form a single monolithic structure.

In one example of a stiffener for a package substrate, the lateral portion comprises two lateral portions configured to be disposed about opposite lateral sides of the package substrate.

In one example of a stiffener for a package substrate, the lateral portion comprises four lateral portions configured to be disposed about four lateral sides of the package substrate.

In one example of a stiffener for a package substrate, the top portion comprises an opening configured to allow one or more electronic components coupled to the package substrate to extend at least partially through the opening.

In one example, a stiffener for a package substrate comprises a bottom portion extending from the lateral portion and configured to be disposed proximate a bottom surface of the package substrate.

In one example of a stiffener for a package substrate, the bottom portion is configured to be affixed to the bottom surface of the package substrate.

In one example of a stiffener for a package substrate, the bottom portion is configured to be affixed to the bottom surface of the package substrate with an adhesive.

In one example of a stiffener for a package substrate, the adhesive is an electrically non-conductive adhesive.

In one example of a stiffener for a package substrate, the top, lateral, and bottom portions form a single monolithic structure.

In one example of a stiffener for a package substrate, the bottom portion is configured to extend from 100 μm to 1 mm from the lateral side of the package substrate along the bottom surface.

In one example of a stiffener for a package substrate, the bottom portion is configured to extend into a ball grid array (BGA) region of the package substrate.

In one example of a stiffener for a package substrate, the bottom portion includes openings configured to allow solder balls to be disposed in the openings.

In one example of a stiffener for a package substrate, one of the openings is configured such that a solder ball in the opening contacts the bottom portion to electrically couple the solder ball and the stiffener to provide electromagnetic interference (EMI) shielding.

In one example of a stiffener for a package substrate, the bottom portion has a thickness of from 50 μm to 200 μm.

In one example of a stiffener for a package substrate, the top portion has a thickness of from 50 μm to 200 μm.

In one example of a stiffener for a package substrate, the lateral portion has a thickness of from 50 μm to 200 μm.

In one example of a stiffener for a package substrate, the stiffener is constructed of a metal material, a ceramic material, a polymer material, a composite material, or a combination thereof.

In one example of a stiffener for a package substrate, the metal material comprises aluminum, steel, magnesium, or a combination thereof.

In one example, there is provided an electronic device package comprising a package substrate having a top surface and a lateral side, an electronic component operably coupled to the top surface of the package substrate, and a stiffener having a top portion affixed to the top surface of the package substrate, and a lateral portion extending from the top portion and disposed about the lateral side of the package substrate.

In one example of an electronic device package, the lateral portion of the stiffener is in contact with the lateral side of the package substrate.

In one example of an electronic device package, the lateral portion of the stiffener extends at least partially about the lateral side between the top surface and a bottom surface of the package substrate.

In one example of an electronic device package, the lateral portion of the stiffener extends about the lateral side from the top surface to a bottom surface of the package substrate.

In one example of an electronic device package, the lateral portion of the stiffener is disposed about greater than or equal to 20% of an area of the lateral side of the package substrate.

In one example of an electronic device package, the top portion of the stiffener is affixed to the top surface of the package substrate with an adhesive.

In one example of an electronic device package, the adhesive is an electrically non-conductive adhesive.

In one example of an electronic device package, the adhesive is an electrically conductive adhesive.

In one example of an electronic device package, the top and lateral portions of the stiffener form a single monolithic structure.

In one example of an electronic device package, the lateral portion of the stiffener comprises two lateral portions disposed about opposite lateral sides of the package substrate.

In one example of an electronic device package, the lateral portion of the stiffener comprises four lateral portions disposed about four lateral sides of the package substrate.

In one example of an electronic device package, the top portion of the stiffener comprises an opening and the electronic component extends at least partially through the opening.

In one example of an electronic device package, the stiffener further comprises a bottom portion extending from the lateral portion and disposed proximate a bottom surface of the package substrate.

In one example of an electronic device package, the bottom portion of the stiffener is affixed to the bottom surface of the package substrate.

In one example of an electronic device package, the bottom portion of the stiffener is affixed to the bottom surface of the package substrate with an adhesive.

In one example of an electronic device package, the adhesive is an electrically non-conductive adhesive.

In one example of an electronic device package, the top, lateral, and bottom portions of the stiffener form a single monolithic structure.

In one example of an electronic device package, the bottom portion of the stiffener extends from 100 μm to 1 mm from the lateral side of the package substrate along the bottom surface.

In one example of an electronic device package, the bottom portion of the stiffener extends into a ball grid array (BGA) region of the package substrate.

In one example of an electronic device package, the bottom portion of the stiffener includes openings, and solder balls are disposed in the openings.

In one example of an electronic device package, one of the openings is configured such that a solder ball in the opening contacts the bottom portion to electrically couple the solder ball and the stiffener to provide electromagnetic interference (EMI) shielding.

In one example of an electronic device package, the bottom portion of the stiffener has a thickness of from 50 μm to 200 μm.

In one example of an electronic device package, the top portion of the stiffener has a thickness of from 50 μm to 200 μm.

In one example of an electronic device package, the lateral portion of the stiffener has a thickness of from 50 μm to 200 μm.

In one example of an electronic device package, the stiffener is constructed of a metal material, a ceramic material, a polymer material, a composite material, or a combination thereof.

In one example of an electronic device package, the metal material comprises aluminum, steel, magnesium, or a combination thereof.

In one example of an electronic device package, the electronic component comprises a processor, a memory device, a system on a chip (SOC), a package on a package (POP), or a combination thereof.

In one example, there is provided a computing system comprising a motherboard, and an electronic device package operably coupled to the motherboard, the electronic device package including a package substrate having a top surface and a lateral side, an electronic component operably coupled to the top surface of the package substrate, and a stiffener having a top portion affixed to the top surface of the package substrate, and a lateral portion extending from the top portion and disposed about the lateral side of the package substrate.

In one example of a computing system, the computing system comprises a desktop computer, a laptop, a tablet, a smartphone, a wearable device, a server, or a combination thereof.

In one example of a computing system, the computing system further comprises a processor, a memory device, a heat sink, a radio, a slot, a port, or a combination thereof operably coupled to the motherboard.

In one example, there is provided a method for coupling a stiffener to a package substrate comprising obtaining a stiffener having a top portion and a lateral portion extending from the top portion, and affixing a top surface of a package substrate to an underside of the top portion of the stiffener, such that the lateral portion of the stiffener is disposed about a lateral side of the package substrate.

In one example, a method for coupling a stiffener to a package substrate comprises disposing the top portion of the stiffener on a carrier with the underside of the top portion exposed and the lateral portion of the stiffener extending away from the carrier.

In one example of a method for coupling a stiffener to a package substrate, the lateral portion of the stiffener is in contact with the lateral side of the package substrate.

In one example of a method for coupling a stiffener to a package substrate, the lateral portion of the stiffener extends at least partially about the lateral side of the package substrate between the top surface and a bottom surface of the package substrate.

In one example of a method for coupling a stiffener to a package substrate, the lateral portion of the stiffener extends about the lateral side of the package substrate from the top surface to a bottom surface of the package substrate.

In one example of a method for coupling a stiffener to a package substrate, the lateral portion of the stiffener is disposed about greater than or equal to 20% of an area of the lateral side of the package substrate.

In one example of a method for coupling a stiffener to a package substrate, affixing the top surface of the package substrate to the underside of the top portion of the stiffener comprises:

disposing an adhesive on the underside of the top portion of the stiffener, the top surface of the package substrate, or both; and

disposing the top surface of the package substrate on the underside of the top portion of the stiffener.

In one example of a method for coupling a stiffener to a package substrate, the adhesive is an electrically non-conductive adhesive.

In one example of a method for coupling a stiffener to a package substrate, the adhesive is an electrically conductive adhesive.

In one example of a method for coupling a stiffener to a package substrate, the top and lateral portions of the stiffener form a single monolithic structure.

In one example of a method for coupling a stiffener to a package substrate, the lateral portion of the stiffener comprises two lateral portions disposed about opposite lateral sides of the package substrate.

In one example of a method for coupling a stiffener to a package substrate, the lateral portion of the stiffener comprises four lateral portions disposed about four lateral sides of the package substrate.

In one example of a method for coupling a stiffener to a package substrate, the top portion of the stiffener comprises an opening configured to receive one or more electronic components coupled to the package substrate.

In one example of a method for coupling a stiffener to a package substrate, the stiffener further comprises a bottom portion extending from the lateral portion.

In one example, a method for coupling a stiffener to a package substrate comprises disposing the bottom portion of the stiffener proximate a bottom surface of the package substrate.

In one example of a method for coupling a stiffener to a package substrate, disposing the bottom portion of the stiffener proximate the bottom surface of the package substrate comprises bending the bottom portion of the stiffener.

In one example of a method for coupling a stiffener to a package substrate, bending the bottom portion of the stiffener comprises rolling the bottom portion of the stiffener.

In one example, a method for coupling a stiffener to a package substrate comprises affixing the bottom portion of the stiffener to the bottom surface of the package substrate.

In one example of a method for coupling a stiffener to a package substrate, affixing the bottom portion of the stiffener to the bottom surface of the package substrate comprises disposing an adhesive on the bottom portion of the stiffener, the bottom surface of the package substrate, or both.

In one example of a method for coupling a stiffener to a package substrate, the adhesive is an electrically non-conductive adhesive.

In one example of a method for coupling a stiffener to a package substrate, the top, lateral, and bottom portions of the stiffener form a single monolithic structure.

In one example of a method for coupling a stiffener to a package substrate, the bottom portion of the stiffener extends from 100 μm to 1 mm from the lateral side of the package substrate along the bottom surface.

In one example of a method for coupling a stiffener to a package substrate, the bottom portion of the stiffener extends into a ball grid array (BGA) region of the package substrate.

In one example of a method for coupling a stiffener to a package substrate, the bottom portion of the stiffener includes openings to receive solder balls coupled to the bottom surface of the package substrate.

In one example of a method for coupling a stiffener to a package substrate, one of the openings is configured such that a solder ball in the opening contacts the bottom portion to electrically couple the solder ball and the stiffener to provide electromagnetic interference (EMI) shielding.

In one example of a method for coupling a stiffener to a package substrate, the bottom portion of the stiffener has a thickness of from 50 μm to 200 μm.

In one example of a method for coupling a stiffener to a package substrate, the top portion of the stiffener has a thickness of from 50 μm to 200 μm.

In one example of a method for coupling a stiffener to a package substrate, the lateral portion of the stiffener has a thickness of from 50 μm to 200 μm.

In one example of a method for coupling a stiffener to a package substrate, the stiffener is constructed of a metal material, a ceramic material, a polymer material, a composite material, or a combination thereof.

In one example of a method for coupling a stiffener to a package substrate, the metal material comprises aluminum. aluminum, steel, magnesium, or a combination thereof.

Circuitry used in electronic components or devices (e.g. a die) of an electronic device package can include hardware, firmware, program code, executable code, computer instructions, and/or software. Electronic components and devices can include a non-transitory computer readable storage medium which can be a computer readable storage medium that does not include signal. In the case of program code execution on programmable computers, the computing devices recited herein may include a processor, a storage medium readable by the processor (including volatile and non-volatile memory and/or storage elements), at least one input device, and at least one output device. Volatile and non-volatile memory and/or storage elements may be a RAM, EPROM, flash drive, optical drive, magnetic hard drive, solid state drive, or other medium for storing electronic data. Node and wireless devices may also include a transceiver module, a counter module, a processing module, and/or a clock module or timer module. One or more programs that may implement or utilize any techniques described herein may use an application programming interface (API), reusable controls, and the like. Such programs may be implemented in a high level procedural or object oriented programming language to communicate with a computer system. However, the program(s) may be implemented in assembly or machine language, if desired. In any case, the language may be a compiled or interpreted language, and combined with hardware implementations.

While the forgoing examples are illustrative of the specific embodiments in one or more particular applications, it will be apparent to those of ordinary skill in the art that numerous modifications in form, usage and details of implementation can be made without departing from the principles and concepts articulated herein.

What is claimed is:

1. An electronic device package, comprising:
a package substrate having a top surface and a lateral side;
an electronic component operably coupled to the top surface of the package substrate; and
a stiffener having
a top portion affixed to the top surface of the package substrate, and
a lateral portion extending from the top portion and disposed about the lateral side of the package substrate.

2. The electronic device package of claim 1, wherein the lateral portion of the stiffener is in contact with the lateral side of the package substrate.

3. The electronic device package of claim 1, wherein the lateral portion of the stiffener extends at least partially about the lateral side between the top surface and a bottom surface of the package substrate.

4. The electronic device package of claim 1, wherein the lateral portion of the stiffener extends about the lateral side from the top surface to a bottom surface of the package substrate.

5. The electronic device package of claim 1, wherein the lateral portion of the stiffener is disposed about greater than or equal to 20% of an area of the lateral side of the package substrate.

6. The electronic device package of claim 1, wherein the top portion of the stiffener is affixed to the top surface of the package substrate with an adhesive.

7. The electronic device package of claim 6, wherein the adhesive is an electrically non-conductive adhesive.

8. The electronic device package of claim 6, wherein the adhesive is an electrically conductive adhesive.

9. The electronic device package of claim 1, wherein the top and lateral portions of the stiffener form a single monolithic structure.

10. The electronic device package of claim 1, wherein the lateral portion of the stiffener comprises two lateral portions disposed about opposite lateral sides of the package substrate.

11. The electronic device package of claim 1, wherein the lateral portion of the stiffener comprises four lateral portions disposed about four lateral sides of the package substrate.

12. The electronic device package of claim 1, wherein the top portion of the stiffener comprises an opening and the electronic component extends at least partially through the opening.

13. The electronic device package of claim 1, wherein the stiffener further comprises a bottom portion extending from the lateral portion and disposed proximate a bottom surface of the package substrate.

14. The electronic device package of claim 13, wherein the bottom portion of the stiffener is affixed to the bottom surface of the package substrate.

15. The electronic device package of claim 14, wherein the bottom portion of the stiffener is affixed to the bottom surface of the package substrate with an adhesive.

16. The electronic device package of claim 15, wherein the adhesive is an electrically non-conductive adhesive.

17. The electronic device package of claim 13, wherein the top, lateral, and bottom portions of the stiffener form a single monolithic structure.

18. The electronic device package of claim 13, wherein the bottom portion of the stiffener extends from 100 μm to 1 mm from the lateral side of the package substrate along the bottom surface.

19. The electronic device package of claim 13, wherein the bottom portion of the stiffener extends into a ball grid array (BGA) region of the package substrate.

20. The electronic device package of claim 19, wherein the bottom portion of the stiffener includes openings, and solder balls are disposed in the openings.

21. The electronic device package of claim 20, wherein one of the openings is configured such that a solder ball in the opening contacts the bottom portion to electrically couple the solder ball and the stiffener to provide electromagnetic interference (EMI) shielding.

22. The electronic device package of claim 13, wherein the bottom portion of the stiffener has a thickness of from 50 μm to 200 μm.

23. The electronic device package of claim 1, wherein the top portion of the stiffener has a thickness of from 50 μm to 200 μm.

24. The electronic device package of claim 1, wherein the lateral portion of the stiffener has a thickness of from 50 μm to 200 μm.

25. The electronic device package of claim 1, wherein the stiffener is constructed of a metal material, a ceramic material, a polymer material, a composite material, or a combination thereof.

26. The electronic device package of claim 25, wherein the metal material comprises aluminum, steel, magnesium, or a combination thereof.

27. The electronic device package of claim 1, wherein the electronic component comprises a processor, a memory device, a system on a chip (SOC), a package on a package (POP), or a combination thereof.
